(19) United States
(12) Patent Application Publication
(10) Pub. No.: US 2010/0304795 A1
(43) Pub. Date: Dec. 2, 2010

(54) Multiple orientation apparatus

(75) Inventors: Aki Laine, Santa Monica, CA (US); Leonard Wozniak, Santa Monica, CA (US); Boris Landwehr, Thousand Oaks, CA (US)

Correspondence Address: HARRINGTON & SMITH, 4 RESEARCH DRIVE, Suite 202, SHELTON, CT, 06484-6212, US

(73) Assignee: Nokia Corporation

(21) Appl. No.: 12/455,196

(22) Filed: May 28, 2009

(51) Int. Cl. H04M 1/00; F16M 11/04; H05K 5/00; H04R 1/02

(52) U.S. Cl. 455/575.1; 248/176.3; 361/679.01; 381/386

(57) ABSTRACT

An apparatus is described with a body having a front side and a rear side. A display is disposed on the front side of the body. Further, there is provided a retractable stand moveable between a compacted configuration and an expanded configuration, connected to the body. The retractable stand is configured to support the body, when the retractable stand is in the expanded configuration, in an orientation selectable from a group of supported orientations, the group of supported orientations including at least two different orientations with a difference of 90 degrees from one orientation to another orientation. The retractable stand is compactable to conform to the generic shape of the body and out of the way when not needed so as to provide good portability.

### TECHNICAL FIELD

The present invention generally relates to a multiple orientation apparatus. The invention relates in particular, though not exclusively, to a portable apparatus that is usable in multiple orientations.

### BACKGROUND

Various portable devices are provided for a plethora of different functions. On the other hand, mobile phones are becoming increasingly rich in features. For instance, there are modern mobile phones with navigation, video playback, email, digital camera and camcorder applications, among others. There may be two different cameras, e.g. a low resolution camera for teleconferencing and a main camera behind the phone for taking digital images with the main camera. Such a phone can be usable in either portrait or landscape direction so that the content on the display is rotated accordingly. However, for extended use such as watching a movie on the display, holding the device in hand at a right orientation may become inconvenient. To this end, there are dedicated stands on which the device can be supported in desired orientation, but such stands should then be separately carried along and erected before use.

### SUMMARY

According to a first exemplary aspect of the invention there is provided an apparatus comprising:
a body comprising a front side and a rear side;
a display disposed on the front side of the body; and
a retractable stand moveable between a compacted configuration and an expanded configuration;
wherein the retractable stand is configured to support the body, when the retractable stand is in the expanded configuration, in an orientation selectable from a group of supported orientations, the group of supported orientations comprising two different orientations with a difference of substantially 90 degrees from one orientation to another orientation.

The group of supported orientations may comprise three different orientations with a difference of substantially 90 degrees from one orientation to another orientation.

The retractable stand may be pivotably moveable between a compacted configuration in which the retractable stand is retracted to the back side of the body and an expanded configuration in which the retractable stand is extended suitably to hold the body in any orientation selected from the group of supported orientations.

The body may comprise two opposite flanks and the retractable stand is pivotably connected to a first flank.

The retractable stand may comprise a lock configured to maintain the retractable stand in the expanded configuration.

The retractable stand may have an attached end configured to reside substantially at the first flank when in the compacted configuration and at the front side when the retractable stand is in the expanded configuration.

The apparatus may further comprise a first device and an operating key. The operating key may be mounted on the retractable stand at the attached end. The key may be configured to control the first device when the retractable stand is in the compacted configuration.

The apparatus may further comprise a second device. The key may be configured to control the second device when the retractable stand is in the expanded configuration.

The apparatus may further comprise a speaker. The retractable stand may be configured to cover the speaker when in the compacted configuration.

The apparatus may further comprise a sensor configured to detect when the retractable stand is in the expanded configuration.

The apparatus may be configured to perform a particular function responsive to the detecting that the retractable stand is in the expanded configuration.

The apparatus may further comprise a slot for a detachable device. The retractable stand may be configured to cover the slot when in the compacted configuration.

The detachable device may be a memory module.

The detachable device may be a subscriber identity module.

The detachable device may be an expansion module such as a PC card.

The retractable stand may be located adjacent to the display.

The apparatus may further comprise a telephone speaker. The retractable stand may be located between the display and the telephone speaker.

The display may be configured to display content in an orientation corresponding to the orientation of the body.

The apparatus may be a portable apparatus.

The apparatus may be a mobile telephone.

computer executable program code configured, when executed by an apparatus that comprises a retractable stand that is retractable and expandable to an expanded configuration in which the retractable stand is configured to support the apparatus in any orientation selected from a group of supported orientations, the group of supported orientations comprising two different orientations with a difference of substantially 90 degrees from one orientation to another orientation, causes the apparatus to perform a particular when responsive to expanding the retractable stand.

The apparatus may be configured as a portable apparatus.

According to a second exemplary aspect there is provided a method comprising:
holding a retractable stand against a body of an apparatus;
extending the retractable stand to an expanded configuration; and
supporting the apparatus in any orientation selected from a group of supported orientations, the group of supported orientations comprising two different orientations with a difference of substantially 90 degrees from one orientation to another orientation.

The method may further comprise detecting when the retractable stand is in the expanded configuration.

The method may further comprise performing a particular function responsive to the detecting that the retractable stand is in the expanded configuration.

According to a third exemplary aspect there is provided a computer program embodied in a computer readable memory medium, comprising:
computer executable program code configured, when executed by an apparatus that comprises a retractable stand that is retractable and expandable to an expanded configuration in which the retractable stand is configured to support the apparatus in any orientation selected from a group of supported orientations, the group of supported orientations comprising two different orientations with a difference of substantially 90 degrees from one orientation to another orientation, causes the apparatus to perform a particular function responsive to expanding the retractable stand.

According to a fourth exemplary aspect there is provided an apparatus comprising:
body means for operating as a body of the apparatus and comprising a front side and a rear side;
display means for displaying information, disposed on the front side of the body means; and
retractable stand means for moving between a compacted configuration and an expanded configuration;
wherein the retractable stand means is configured to support the body means, when the retractable stand means is in the expanded configuration, in an orientation selectable from a group of supported orientations, the group of supported orientations comprising two different orientations with a difference of substantially 90 degrees from one orientation to another orientation.

Different non-binding exemplary aspects and embodiments of the present invention have been illustrated in the foregoing. Some embodiments may be presented only with reference to certain exemplary aspects of the invention. It should be appreciated that corresponding embodiments may apply to other exemplary aspects as well.

### BRIEF DESCRIPTION OF THE DRAWINGS

The invention will be described, by way of example only, with reference to the accompanying drawings, in which:

FIG. 1 presents a schematic drawing of an example embodiment of the invention;

FIG. 2 shows a schematic drawing of the example of FIG. 1 seen from a side in a portrait orientation;

FIG. 3 shows a cross section of a detail of the example of FIG. 1;

FIG. 4 shows a schematic drawing of the example of FIG. 1 seen from a side in a first landscape orientation;

FIG. 5 shows a schematic drawing of the example of FIG. 1 seen from a side in a second landscape orientation; and

FIG. 6 shows a block diagram of an example embodiment of the invention.

### DETAILED DESCRIPTION

In the following description, like numbers denote like elements.

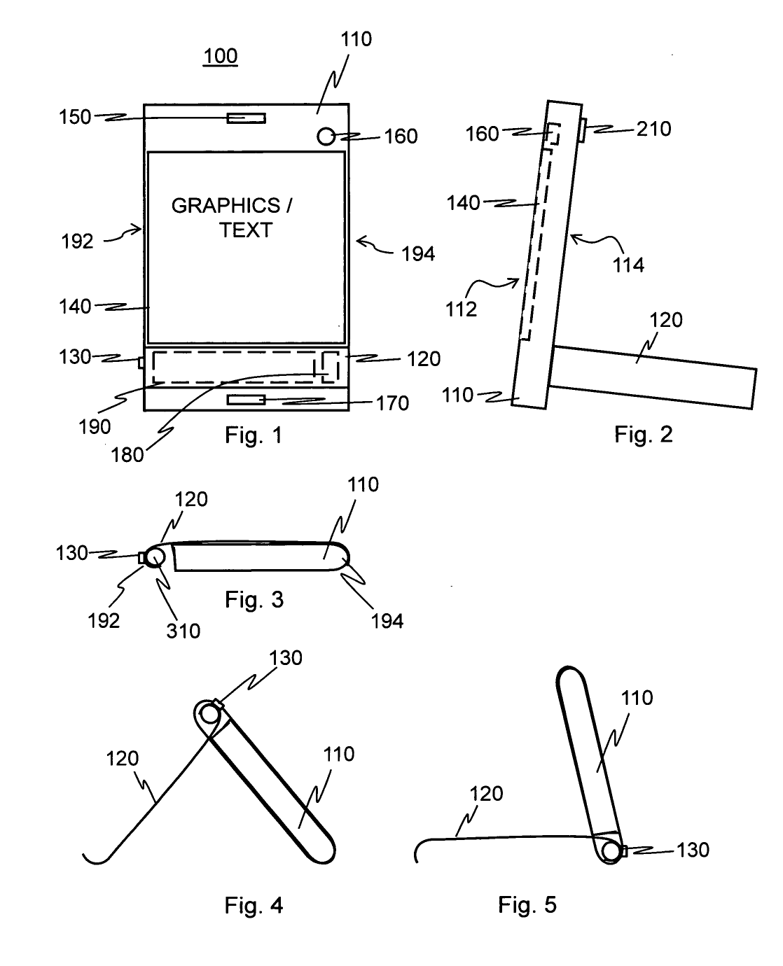

FIG. 1 shows a schematic drawing of an apparatus, here of a mobile communication device 100, according to an example embodiment of the invention. The apparatus comprises a body 110, a retractable stand 120 connected to the body, a control key 130 connected to the retractable stand 120, a display 140, a phone speaker 150, a front camera 160, and a microphone 170. The apparatus 100 further comprises, behind or covered by the retractable stand 120, a slot or connector 180 for external devices such as memory cards, and a hands-free speaker 190.

The retractable stand 120 in FIG. 1 is connected to an axle within the body such that the retractable stand 120 can be compacted to a corresponding groove in the body 110 in a front surface of the apparatus 100. This compacted configuration enables retracting the stand such that it does not hinder portable use of the apparatus 100. On the other hand, the retractable stand 120 can be expanded by rotating about its connection axel such that the retractable stand 120 extends on a rear side of the apparatus and can thus support the apparatus in a portrait or landscape orientation. FIG. 2 demonstrates the apparatus in a portrait orientation when resting on the retractable stand against a horizontal surface such as a desk top. FIG. 2 also shows a rear camera or main camera 210 that is usable for digital photography or camcorder applications.

The apparatus is drawn as a generally rectangular object with a front a display on a front side 112 (FIG. 2) and the main camera 210 on a rear side 114 (FIG. 2) and with two flanks 192, 194 or sides as seen in FIG. 1. In this document, a flank refers to a side wall, whether curved or straight, that resides at a side of the apparatus 100.

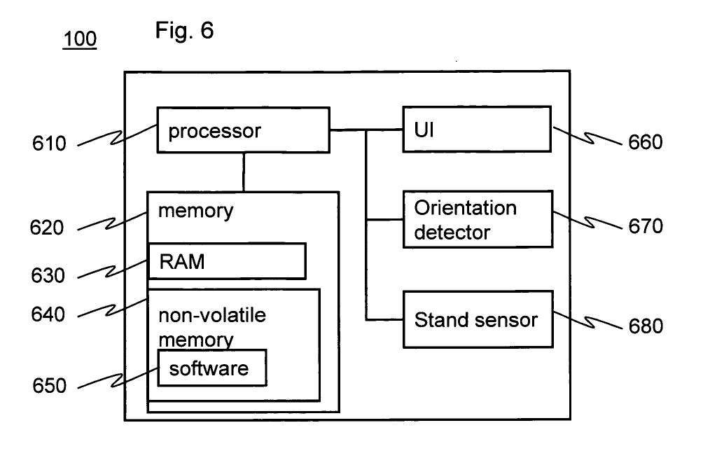

FIG. 3 shows a cross section of a detail of the apparatus in FIG. 1. FIG. 3 represents a section through the control key 130 and across the retractable stand 120, but omits the hands-free speaker 190 and the slot 180. FIG. 3 also presents an axle 310 through which the retractable stand 120 is supported to the body 110 and the control key 130 is connected to internal circuitry (see FIG. 6 for a block diagram) of the apparatus 100.

FIG. 4 shows a schematic drawing of the example of FIG. 1 seen from a side in a first landscape orientation. In this orientation, the control key 130 resides near the top of the apparatus 100. The control key 130 provides an easy access for the user to particular functions or services. For instance, the control key 130 may be used in the orientations shown in FIGS. 2, 4 and 5 for enabling and disabling the front camera 160 during a telephone call or before a telephone call to signal start or end of transmission of video image of the user. Alternatively, the control key 130 may be used to start or stop playing of a media file or media stream, if the apparatus is used for playing back visual or audible content such as a video, movie or music.

The apparatus 100 may comprise a lock to restrict changing of the orientation of the retractable stand 120. The lock may be formed, for instance, by forming suitable corners to the axle 310 and by forming a tension force in the end of the retractable stand 120 that surrounds the axle 310. Thus, a resilient bias may be formed that produces a snap action on expanding and compacting the retractable stand. Alternatively, or additionally, there may be a latch, magnet, pin and correspondingly arranged hole or snug fitting between the axle 310 and the attached end of the retractable stand 120 provided to function as the lock.

The apparatus 100 may also comprise a sensor 680 configured to detect when the retractable stand 120 is expanded (and/or when the retractable stand 120 is compacted) and the apparatus may be configured to operate in a predetermined manner accordingly. For instance, when the retractable stand 120 is expanded, the apparatus may provide a menu of particular short-cuts to features that are commonly used when the retractable stand is expanded. Such features may include placing a phone call or video call, listening to music, watching photographs, browsing in the Internet with a web-browser, and/or watching a movie (either locally stored or streamed down from a remote source).

The apparatus may also comprise an orientation detector 670 (FIG. 6) configured to identify the orientation of the apparatus and to control the display 140 to present information in a corresponding direction (portrait or landscape that is rotated to the left or right hand side from the portrait orientation).

The sensor for detecting the configuration of the retractable stand 120 and the orientation detector are functionally presented in the block diagram 6.

FIG. 5 shows a schematic drawing of the example of FIG. 1 seen from a side in a second landscape orientation. In this orientation, the display is more upright than in the first landscape orientation shown in FIG. 4. This orientation may be particularly useful in applications in which the apparatus is placed higher in relation to the eyes of the user. Such events may occur for instance in an airplane, train or in car (where the passenger may place a portable apparatus onto a tray behind a front seat).

FIG. 6 shows a block diagram of an example embodiment of the invention. FIG. 6 shows particular functional blocks or elements that facilitate understanding one way to produce the apparatus 100. The circuitry of the apparatus 100 may comprise a processor 610, a memory 620 including a work memory or random access memory 630, a persistent or non-volatile memory 640 and software 650 stored in the non-volatile memory. The software 650 may include operating system, device drivers and application programs to control the operation of the apparatus 100. The processor is configured to execute the software 650 and accordingly control the operation of the apparatus 100.

The apparatus 100 further comprises a user interface 660 that includes the display 140, the microphone 170, the phone speaker 150, the front camera 160, the main camera 210 and touch keys provided by the display 140 (as a touch screen) and/or any dedicated keys such as the control key 130. Moreover, the apparatus may further comprise the orientation detector 670 configured to detect the orientation of the apparatus. This detector may be based on a conductive drop of liquid in a chamber that has contacts which become closed depending on the orientation of the apparatus 100. The apparatus may also comprise the stand sensor to detect the configuration of the stand 120.

It is appreciated that a device as described with reference to FIGS. 1 to 5 may provide a retractable stand that is expandable to hold the apparatus in a desired orientation, but which retractable stand is also compactable to conform to the generic shape of the body and out of the way when not needed so as to provide good portability for the apparatus. The retractable stand may also cover and protect such parts of the apparatus that are not normally needed when the apparatus is held in a pocket or hand. For instance, an internal hands-free speaker or stereo speakers may be provided under cover of the retractable stand when the retractable stand is in the compacted configuration, while making such parts fully accessible or better audible when the retractable stand is in the expanded configuration. The retractable stand may be configured such that in the compacted configuration, an acoustic passage is left around, through or via the retractable stand (from the hands-free speaker). For instance, holes may be formed in the retractable stand to allow passage of sounds, the retractable stand may comprise a thin section of a foil, for instance, to allow passage of sounds via the retractable stand or suitable cavities or openings may be left around the retractable stand so as to allow passage of sounds around the retractable stand. However, in particular embodiments, the internal hands-free speaker is enabled or becomes usable only when the retractable stand is in the expanded configuration. Further, the retractable stand may be used to provide an easy access to a memory card or expansion card while concealing such parts during transport and thus protecting them against becoming mechanically damaged or lost while the retractable stand is in the compacted configuration.

The foregoing description has provided by way of non-limiting examples of particular implementations and embodiments of the invention a full and informative description of the best mode presently contemplated by the inventors for carrying out the invention. It is however clear to a person skilled in the art that the invention is not restricted to details of the embodiments presented above, but that it can be implemented in other embodiments using equivalent means or in different combinations of embodiments without deviating from the characteristics of the invention.

Furthermore, some of the features of the above-disclosed embodiments of this invention may be used to advantage without the corresponding use of other features. As such, the foregoing description shall be considered as merely illustrative of the principles of the present invention, and not in limitation thereof. Hence, the scope of the invention is only restricted by the scope and spirit of the appended patent claims.

1. An apparatus comprising:
a body comprising a front side and a rear side;
a display disposed on the front side of the body; and
a retractable stand moveable between a compacted configuration and an expanded configuration;
wherein the retractable stand is configured to support the body, when the retractable stand is in the expanded configuration, in an orientation selectable from a group of supported orientations, the group of supported orientations comprising two different orientations with a difference of substantially 90 degrees from one orientation to another orientation.

2. An apparatus according to claim 1, wherein the group of supported orientations comprises three different orientations with a difference of substantially 90 degrees from one orientation to another orientation.

3. An apparatus according to claim 1, wherein the retractable stand is pivotably moveable between a compacted configuration in which the retractable stand is retracted to the back side of the body and an expanded configuration in which the retractable stand is extended suitably to hold the body in any orientation selected from the group of supported orientations.

4. An apparatus according to claim 4, wherein the body comprises two opposite flanks and the retractable stand is pivotably connected to a first flank.

5. An apparatus according to claim 1, wherein the retractable stand comprises a lock configured to maintain the retractable stand in the expanded configuration.

6. An apparatus according to claim 5, wherein:
the retractable stand has an attached end configured to reside substantially at the first flank when in the compacted configuration and at the front side when the retractable stand is in the expanded configuration.

7. An apparatus according to claim 6, wherein:
the apparatus further comprises a first device and an operating key;
the key is mounted on the retractable stand at the attached end; and
the key is configured to control the first device when the retractable stand is in the compacted configuration.

8. An apparatus according to claim 7, wherein:
the apparatus further comprises a second device; and
the key is configured to control the second device when the retractable stand is in the expanded configuration.

9. An apparatus according to claim 1, wherein:
the apparatus further comprises a speaker; and
the retractable stand is configured to cover the speaker when in the compacted configuration.

10. An apparatus according to claim 9, wherein:
the apparatus comprises a sensor configured to detect when the retractable stand is in the expanded configuration.

11. An apparatus according to claim 10, wherein:
the apparatus is configured to perform a particular function responsive to the detecting that the retractable stand is in the expanded configuration.

12. An apparatus according to claim 1, wherein:
the apparatus further comprises a slot for a detachable device; and
the retractable stand is configured to cover the slot when in the compacted configuration.

13. An apparatus according to claim 12, wherein the detachable device is a memory module.

14. An apparatus according to claim 1, wherein:
the retractable stand is located adjacent to the display.

15. An apparatus according to claim 14, wherein:
the apparatus further comprises a telephone speaker; and
the retractable stand is located between the display and the telephone speaker.

16. An apparatus according to claim 1, wherein:
the display is configured to display content in an orientation corresponding to the orientation of the body.

17. An apparatus according to claim 1, wherein:
the apparatus is a portable apparatus.

18. An apparatus according to claim 1, wherein:
the apparatus is a mobile telephone.

19. A computer program embodied in a computer readable memory medium comprising:
computer executable program code configured, when executed by an apparatus that comprises a retractable stand that is retractable and expandable to an expanded configuration in which the retractable stand is configured to support the apparatus in any orientation selected from a group of supported orientations, the group of supported orientations comprising two different orientations with a difference of substantially 90 degrees from one orientation to another orientation, causes the apparatus to perform a particular function responsive to expanding the retractable stand.

20. An apparatus comprising:
body means for operating as a body of the apparatus and comprising a front side and a rear side;
display means for displaying information, disposed on the front side of the body means; and
retractable stand means for moving between a compacted configuration and an expanded configuration;
wherein the retractable stand means is configured to support the body means, when the retractable stand means is in the expanded configuration, in an orientation selectable from a group of supported orientations, the group of supported orientations comprising two different orientations with a difference of substantially 90 degrees from one orientation to another orientation.
